(19) United States
(12) Patent Application Publication
(10) Pub. No.: US 2025/0355085 A1
(43) Pub. Date: Nov. 20, 2025

(54) TEST ARRANGEMENT FOR A SENSOR

(71) Applicant: dSPACE GmbH, Paderborn (DE)

(72) Inventors: Christian SCHAEFERS, Paderborn (DE); Moritz DICKHUT, Paderborn (DE)

(73) Assignee: dSPACE GmbH, Paderborn (DE)

(21) Appl. No.: 19/232,437

(22) Filed: Jun. 9, 2025

Related U.S. Application Data
(63) Continuation of application No. PCT/EP2023/084723, filed on Dec. 7, 2023.

(30) Foreign Application Priority Data
Dec. 20, 2022 (DE) 10 2022 134 006.6

(51) Int. Cl. G01S 7/40

(52) U.S. Cl. CPC G01S 7/4086

(57) ABSTRACT

A test arrangement for a sensor, which is designed to detect objects by sending first electromagnetic signals and receiving second electromagnetic signals. The test arrangement has a chamber with a receptacle for the sensor. The chamber has at least two transmission/receiving devices which are configured to receive first signals transmitted from the sensor to the chamber and to transmit second signals for reception for the sensor. The at least two transmission/receiving devices each have an emitting element for emitting the second signals, wherein a spacing device is provided via which the distance of the at least two emitting elements from one another can be changed in exactly one spatial direction.

This nonprovisional application is a continuation of International Application No. PCT/EP2023/084723, which was filed on Dec. 7, 2023, and which claims priority to German Patent Application No. 10 2022 134 006.6, which was filed in Germany on Dec. 20, 2022, and which are both herein incorporated by reference.

### BACKGROUND OF THE INVENTION

### Field of the Invention

The application relates to a test arrangement for a sensor. The sensor operates using electromagnetic waves and the evaluation of electromagnetic transmission signals and electromagnetic received signals.

### Description of the Background Art

From WO 2020/127984 A1, which corresponds to US 2022/0082700, which is incorporated herein by reference, a test bench for testing a distance sensor that operates using electromagnetic waves is known, wherein the distance sensor to be tested includes at least one sensor emitting element for emitting a transmission signal and a sensor receiving element for receiving a reflection signal. The test bench has a receptacle for mounting the distance sensor to be tested having an at least partially movable baffle in the emission range of a distance sensor held in the receptacle. At least one test bench-receiving element held in the baffle is provided to receive the transmission signal emitted by the sensor emitting element. At least one test bench emitting element held in the baffle is provided for emitting a test bench transmission signal as a simulated reflection signal. A reliable environmental simulation, especially for the testing of multiple-input-multiple-output distance sensors, is achieved by arranging at least one test bench receiving element and one test bench emitting element together in a moving part of the baffle.

From WO 2017/198613 A1, an antenna measurement chamber is known for measuring the antenna properties of HF antennas, wherein the following is provided: a complete lining with a plurality of absorbers on their inner boundary surfaces, separate supports for an antenna to be tested and for a transmitting antenna, a double bottom for invisible cable routing of the supply and control cables of the antennas, a carrier designed as a movable carriage for one of the two antennas, which can be moved on the lower of the two bottoms of the double bottom and which penetrates the upper floor with the lining on it.

A test bench for testing an environmental sensor that operates with electromagnetic waves is known from DE 102019123155 A1, which is incorporated herein by reference, wherein the environmental sensor to be tested comprises at least one sensor emitting element for emitting a transmission signal and a sensor receiving element for receiving a reflection signal, with a receptacle for the holder of the environment sensor to be tested, with at least one swivel arm with a rotation axis and wherein a first test bench emitting element and/or a first test bench receiving element is held on the swivel arm which can be moved by means of the swivel arm independently of the orientation of the swivel arm about the axis of rotation in the field of view of an environmental sensor held in the receptacle and wherein the test bench receiving element is set up to receive the transmission signal emitted by the sensor emitting element and wherein the test bench receiving element is set up for emitting a test bench transmission signal as a simulated reflection signal, wherein the swivel arm has a support device which has a sliding bearing.

### SUMMARY OF THE INVENTION

It is therefore an object of the present to provide a test arrangement for a sensor. In an example, the sensor can be designed to detect objects by sending first electromagnetic signals and receiving second electromagnetic signals. The test arrangement can have a chamber with a receptacle for the sensor. The chamber furthermore can have at least two transmission/receiving devices which are configured to receive first signals transmitted from the sensor into the chamber and to transmit second signals for reception for the sensor, wherein the at least two transmission/receiving devices may each have an emitting element for emitting the second signals. A spacing device can be provided by means of which the distance of the at least two emitting elements from one another can be changed in exactly one spatial direction.

The test arrangement for a sensor has the advantage that the spacing device, by means of which the distance of the at least two emitting elements from one another can be changed in exactly one spatial direction, allows for a cost-effective and simple angular separation measurement by means of the test arrangement. Such an angular separation measurement measures the angle at which the sensor can still separately perceive received second signals that have been reflected at two adjacent objects.

The possibility of changing the distance between the at least two emitting elements in only one linear spatial direction makes it possible to precisely test this parameter in a more targeted manner.

In particular, the sensor for object detection can be an environment sensor for use in a vehicle. Such environment sensors operate using electromagnetic waves and are used, for example, as distance sensors. For example, radar sensors with wavelengths in the microwave range are used for this purpose. However, the test arrangement is also suitable for sensors, especially environmental sensors, which operate in a different frequency range of electromagnetic waves, for example in the visible light range, or that operate with electromagnetic emitting sources that emit electromagnetic waves with a long coherence length, such as in laser applications (e.g., LIDAR).

The sensor, in particular the environment sensor, can send out first signals and receive their reflection as second signals. By evaluating the first and second signals, information can be obtained about the existence of objects, their distance, relative velocity, and/or other properties of the object such as size and/or surface properties.

A test arrangement is a device that is set up to test sensors for object detection before they are installed in vehicles, for example. For this purpose, this test arrangement has a receptacle as a mount to hold the sensor as a so-called Device Under Test. The sensor can thus emit first electromagnetic signals into the chamber of the test arrangement and in turn receive second electromagnetic signals from the chamber. This allows for the functionality of the sensor to be reliably tested by the test arrangement.

For this purpose, the test arrangement has transmission/receiving devices that can simulate objects by receiving first signals from the sensor and emitting second signals to the sensor. The test arrangement offers the advantage that by changing the spacing between the emitting elements, it can be ascertained at which distance between two emitting elements, i.e., between two simulated objects, such a sensor can still just barely distinguish these two objects.

The test arrangement therefore offers not only the mechanical setup for mounting the sensor in a receptacle, but also its own transmission/receiving devices that receive the first signals emitted by the sensor and send the second signals to the sensor. For this purpose, corresponding controls and evaluations are then also available on, e.g., a computing unit to round off such a test arrangement. Such test arrangements make it possible to test the sensor in many situations before installing the sensor in, e.g., a vehicle.

The sensor according to the application can be, for example, a radar or a lidar sensor. The radar sensor can transmit the first signals at 24 GHZ, 60 GHZ, or 77 GHz, for example. The lidar signals, for example, are broadcast in the near infrared. For this purpose, the sensor has a transmitter, such as a radar or lidar transmitter, and a receiver, i.e., a corresponding radar or lidar receiver.

A radar or lidar sensor can be used for object detection. This means that such a sensor can be designed to detect, classify and/or then track an object. An important criterion is that the sensor can distinguish two objects from each other, even if they are close to one another. Especially at a greater distance, this is a requirement that such sensors must reliably meet.

The spacing device makes it possible to linearly vary the distance between the emitting elements in exactly one spatial direction in order to vary the distance between simulated objects and thus determine at what distance two objects are no longer distinguishable for the sensor or are just barely distinguishable. The spacing device is configured to enable the change of the position and thus the distance of the at least two emitting elements from one another in one spatial direction and at the same time to fix their position and thus distance in the other spatial directions.

The test arrangement can have a chamber into which the sensor can send the first signals and from which the sensor can receive the second signals. This provides a defined environment for testing the sensor. In particular, such a chamber can be lined with appropriate absorbers to avoid unwanted reflections, so that only the second signals emitted by the at least two transmission/receiving devices are visible to the sensor and received accordingly and interference emitting is largely eliminated.

The at least two transmission/receiving devices can therefore be configured for transmitting and receiving radar emission or lidar emission, just like the sensor itself. However, they can be simpler, the same, or more complex. They must receive the first signals and, depending on the first signals, be able to send such second signals that an object is simulated for the sensor. This enables controlled simulation in the chamber. The two transmission/receiving devices therefore each have an emitting element for emitting the second signals. In the case of a radar sensor, the emitting elements can be transmitting antennas, for example. In the case of a lidar sensor, the emitting elements can be optical emitters, for example.

In particular, the test arrangement offers the advantage that the position of the emitting elements can be changed in relation to one another. This is important because the resolution of the emitting points is to be tested. This means that the aim is to have the points from where the second signals are sent to the sensor as close as possible to one another in order to test the finest possible resolution.

The spacing device, makes it possible to linearly change the distance between the at least two emitting elements in exactly one spatial direction. This linear spatial direction can be, for example, the horizontal, but also the vertical. In the case of a horizontal change, a so-called azimuth angle is found, under which two objects can still be distinguished. If the two emitting elements are vertically spaced, the minimum elevation angle is determined at which the two emitting elements can still be distinguished from one another.

The test arrangement thus offers the advantage that the emitting elements of the transmission/receiving devices can be changed in only one spatial direction and that they can be fixed in one spatial direction with respect to the other directions.

The test arrangement thus offers the advantage that the emitting elements of the transmission/receiving devices can be installed, for example, at the same height, i.e., at the same elevation angles, and only the lateral distance, i.e., the azimuth angle, can be varied during testing.

Furthermore, the emitting elements of the transmission/receiving devices can be installed on the same vertical line, i.e., at the same azimuth angle, with only the height, i.e., the elevation angle, possibly varying during testing.

If, in addition to the emitting element, a separate receiving element is also used for each transmission/receiving device, the position of the receiving element can be changed together with the emitting element in an example so that no phase shift is introduced between the receiving element and the emitting element. It is advantageous to keep the emitting and receiving elements of a transmission/receiving device as close as possible to one another in order to avoid phase shifts. The sensor expects the response from the same direction to where it has transmitted. For this reason, it is preferable to move the emitting element and receiving element together.

The spacing device can have at least one rail with which the distance of the at least two emitting elements from one another can be changed in exactly one spatial direction. A rail can be used to change the distance particularly accurately and reliably. This can then be done manually or automatically, for example. In order to change the distance in the linear spatial direction, the rail is designed in particular as a straight rail, which allows for the emitting elements to move on a straight path in space.

Furthermore, it is proposed that the distance of the at least two transmission/receiving devices to one another can be changed in exactly one spatial direction with the spacing device, wherein the spacing device in particular has at least one rail with which the distance of the at least two transmission/receiving devices to one another can be changed in exactly the one spatial direction. This means that it is possible to change the position of the at least two transmission/receiving devices with the respective emitting elements together on the rail. It is also given here that the distance remains unchanged in other spatial directions. In this embodiment, too, the rail is straight, so that the change in distance takes place in a linear direction.

The spacing device can have a first actuator for manual change of the distance and/or a second actuator for automatic modification of the distance. With a manual change of the distance, the distance can then be changed individually depending on the respective situation without having to enter further data. With an automatic change of the distance, it is possible to use predefined test programs and/or to respond dynamically to the reaction of the sensor. For example, it can be used to adjust the distance depending on the second signals and/or evaluations that the sensor makes. This can then be used to determine the distance very precisely at which the two objects are still just barely distinguishable or are no longer distinguishable.

In addition, the chamber may have several modules, with the modules enlarging the chamber in at least one direction, wherein the direction extends in particular from the sensor to the emitting elements or the transmission/receiving devices. This modular design makes it possible to adjust the distance between the sensor and the emitting elements or the transmission/receiving devices depending on the test requirements or the characteristics of the sensor. This allows for tests to be extended to greater distances.

Furthermore, the receptacle can be designed to change a position and/or orientation of the sensor. This means that the sensor is not only fixed in a rigid position, but can also be changed in its position, so that the geometric position of the sensor and the at least two transmission/receiving devices can be changed as a supplement to the spacing device. The orientation of the sensor, in which direction the sensor radiates the first signals, can also be changed. This then enables a very precise assessment of the quality of the object detection for the sensor.

As already described above, the chamber in its interior can be essentially lined with a material that will absorb electromagnetic signals.

The at least two transmission/receiving devices can each have a receiving element for receiving the first signals, wherein the emitting element and the receiving element of a respective transmission/receiving device can be located in an area of the wall in the interior of the chamber and the spacing device is located outside the chamber. This has the advantage that the spacing device does not have to be specially clad to avoid unwanted reflections by the spacing device. In addition, the spacing device can be serviced or operated more easily outside the chamber.

In addition, it is provided that the at least two transmission/receiving devices can each have a transmitting transducer and a receiving transducer, with the transmitting transducer and the receiving transducer of a respective transmission/receiving device being located outside the chamber. This also has the advantage that the test arrangement is easier to operate if, for example, a transmitting or receiving transducer has to be replaced and a cladding of these two transducers within the chamber is also not necessary to avoid reflections. The respective emitting element of a respective transmission/receiving device is connected to the transmitting transducer via a waveguide. In particular, the transmitting transducer converts electrical baseband signals, such as those received as working signals via an interface of the transmitting/receiving element, into modulated high-frequency signals, such as those that can be emitted by the emitting unit. The respective receiving element of a respective transmission/receiving device is connected to the receiving transducer via a waveguide. In particular, the receiving transducer converts the modulated high-frequency signals emitted by the receiving element into baseband signals, which can then be output as working signals, for example, via the interface of the transmitting/receiving element.

Furthermore, it is proposed that the area in the wall of the chamber can have a slot through which the respective emitting elements are connected to the respective transmitting transducers via waveguides and respective receiving elements are connected to the respective receiving transducers via waveguides. The connections can then be routed through the slot, i.e., an elongated opening in the chamber wall. The slot can also be easily covered in a simple manner to avoid reflections on these feed-throughs. Waveguides are preferably provided for the connection to the transducers in order to be able to reliably transmit the high-frequency signals. In addition, it is possible that the slot, especially on the inside of the chamber, is essentially covered with the absorbent material.

The area can be designed as a wall insert for an opening of the wall, wherein the wall insert can be inserted in the wall of the chamber in at least two different orientations. This allows for the insert, for example, to be used at different angles by 90° in order to check either the azimuth angle or the elevation angle.

The emitting element and the receiving element of a respective transmission/receiving device can be designed as a combined emitting/receiving element. Especially for a radar sensor, the emitting element can be designed as a transmitting antenna and the receiving element as a receiving antenna.

The transmitting antenna and the receiving antenna can optionally be designed as a single antenna, wherein this antenna can be designed in particular as a horn antenna or as a curved antenna. Such measures make it possible to save material, i.e., horn, or curved antennas are particularly suitable for the present purpose in order to enable a particularly small distance between the emitting elements and the respective transmitting/receiving devices.

Furthermore, such combined antennas of a respective transmission/receiving device can be connected to a transceiver via respective waveguides, wherein the transceiver comprises the transmitting transducer and the receiving transducer of the respective transmission/receiving device.

The sensor can be designed as a radar sensor as indicated above or alternatively as a lidar sensor.

In a method for testing a sensor that is designed to detect objects by sending first electromagnetic signals and receiving second electromagnetic signals, the sensor is first positioned in the receptacle in an orientation to the transmitting/receiving devices. Thereafter, the distance between the respective emitting elements of the transmission/receiving devices is linearly varied in one spatial direction. The varying of the distances can also be done automatically, e.g., for automated test sequences.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a schematic view of the test arrangement,

FIG. 2 shows a schematic view of a transmission/receiving device,

FIG. 3 shows a schematic view of the two transmission/receiving devices on a rail,

FIG. 4 shows a schematic view of the rail,

FIG. 5 shows a schematic overall view of the test arrangement, and

FIG. 6 shows another schematic view of the multi-module test arrangement.

### DETAILED DESCRIPTION

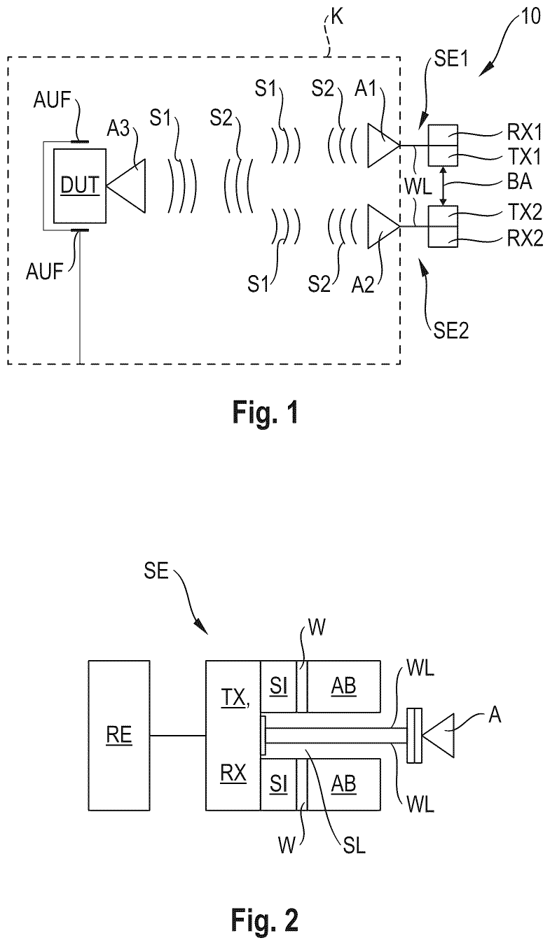

FIG. 1 shows a test arrangement 10 in a schematic view, in which a sensor DUT sits with its antenna A3 in a receptacle AUF. In the example shown, the sensor DUT is a sensor that has antennas for emitting and receiving the signals S1, S2, e.g., a radar sensor.

The sensor DUT emits first signals S1 into the chamber K with its antenna A3. On the opposite side, two transmission/receiving devices SE1 and SE2 are arranged on the chamber K, wherein the two respective antennas A1 and A2 of the two transmission/receiving devices SE1 and SE2 are located within the chamber K. Outside the chamber K, the two transmission/receiving devices SE1 and SE2 each have a transmitting transducer TX1, TX2 and a receiving transducer RX1 or RX2. Between the two transmission/receiving devices SE1 and SE2, a spacing device BA is arranged, which changes the distance between the two transmission/receiving devices SE1 and SE2 in exactly one spatial direction, which is in particular a linear direction in space.

The sensor DUT is also set up to receive the second S2 signals via its antenna A3 and to carry out evaluations. The antenna A3 is therefore a combined transmitting and receiving antenna.

Using the spacing device BA, it is possible to change the position between the transmission/receiving devices SE1 and SE2 automatically or manually. The antennas A1 and A2 are used both to emit the second signals S2 and to receive the first signals S1. These are therefore antennas A1, A2, in which transmitting antenna and receiving antenna are combined into one antenna A1, A2. They are each connected via waveguides to the transmitting or receiving transducers TX1, TX2, RX1, RX2 of the transmission/receiving devices SE1 and SE2.

FIG. 2 shows a transmitter/receiving device SE in a further schematic representation. The antenna A is connected to the receiving RX or transmitting transducer TX via the waveguide WL. The transmitting and receiving transducers TX and RX are in turn connected to a computer RE on the other side. The receiving transducer RX converts the first signals S1 into working signals so that they can be transmitted to the computer RE for further processing, wherein the computer RE controls the transmitting transducer TX via further working signals in order to emit the second signals S2 via the waveguide WL and the antenna A.

The waveguides WL are guided through a slot SL in the wall W of the chamber K. The wall W is covered by absorbent material AB inside the chamber K, so that no unwanted reflections are generated by the first signals S1. Therefore, the absorbent material AB is arranged on the wall W of the chamber K. In the example shown, the spacing device BA is designed as a rail SI. Behind the wall W is the rail SI, which makes it possible to change the distance between antenna A and another antenna A. It is possible that other components of the transmission/receiving device SE, in particular the transmitting transducers TX and/or the receiving transducers RX, remain at their respective locations outside of the chamber K. It is also possible that, in addition to the antennas A of the transmission/receiving devices SE, the transmission/receiving devices SE with their transmitting transducers TX and their receiving transducers RX are also changed in their distance from on another via the rail SI. The distance between the antennas A is technically decisive since they emulate the reflections of the first signals S1 by their transmitted second signals S2.

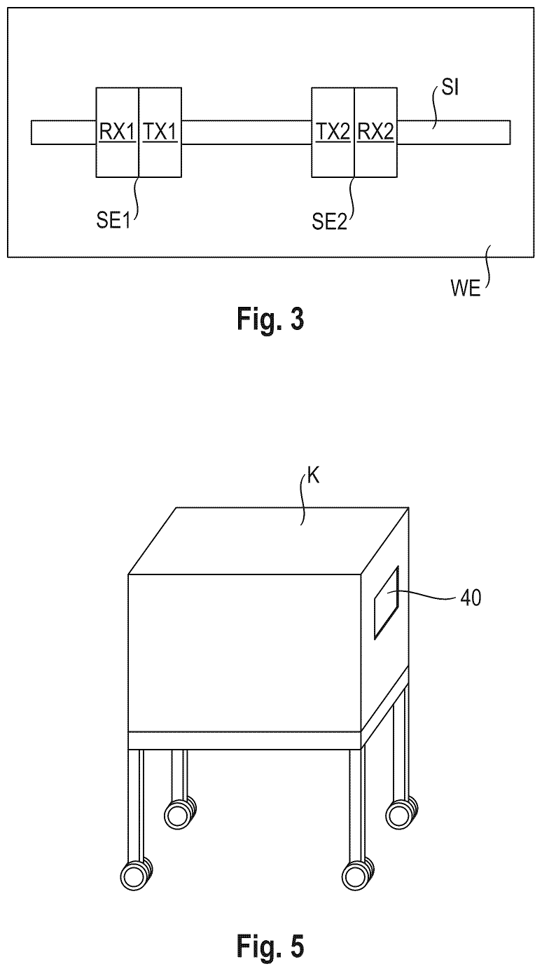

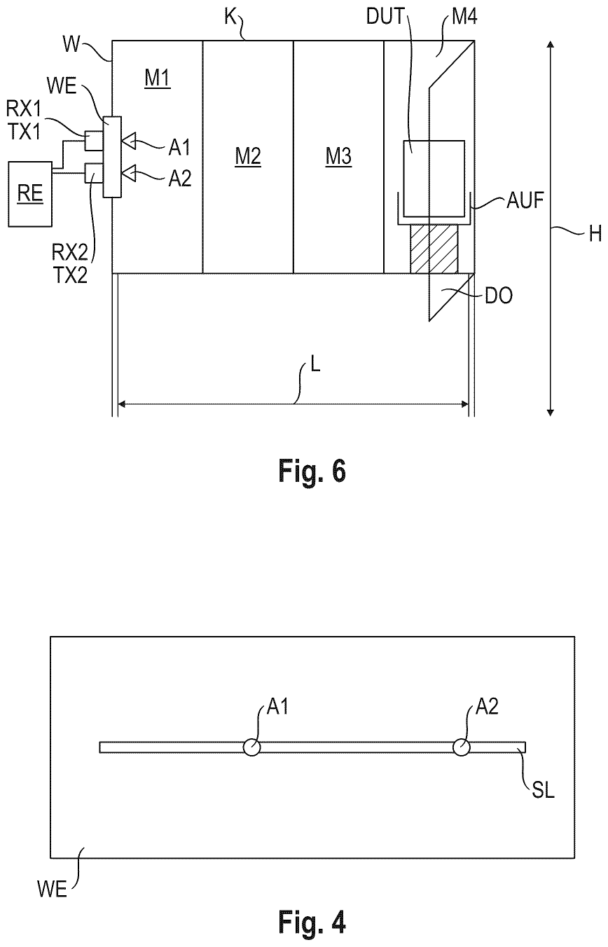

FIG. 3 shows in a schematic representation a wall insert WE for an opening 40 of the chamber K (FIG. 4) with the rail SI and the receiving transducers RX1, RX2 as well as the transmitting transducers TX1 and TX2 of the two transmission/receiving devices SE1 and SE2. The rail SI with the receiving transducers RX1, RX2 and the transmitting transducers TX1 and TX2 is located outside the chamber. Thus, the wall insert WE is shown as it looks when viewed from outside the chamber K.

FIG. 4 shows a view of the other side of the wall element WE, as it would appear in the installed state of the wall element WE when viewed from inside the chamber K. The two antennas A1 and A2 are located in front of the slot SL within the chamber K.

They are connected via waveguides WL through the slot SL to their respective transmission/receiving transducers TX1, TX2, RX1, RX2. The transmission/receiving devices SE1, SE2 can thus be moved together with their antennas A1, A2 via the rail SI. This makes it possible to change the distance between the transmission/receiving devices SE1, SE2 and therefore also the antennas A1, A2 in the direction of the rail SI.

The slot SL can be covered by the absorbent material AB and thus also substantially cover the rail SI installed outside the chamber K. The absorbent material AB can then also be provided with a slot, for example, and widened by the waveguides WL and/or the antennas A1, A2 only at the point where the waveguides or antennas are routed through the slot SL and the slot in the absorbent material AB.

FIG. 5 shows in a schematic representation the test arrangement 10 on a frame with the chamber K and the opening 40, into which the previously described wall insert WE can be inserted. On the opposite side of the chamber K, the sensor DUT is then provided. The representation is schematic, and the wall insert WE can be larger or smaller than it is shown in the figure relative to the wall of the chamber K.

FIG. 6 shows the entire test arrangement 10 with the length L in the horizontal direction and the height H in the vertical direction, the chamber K now consisting of several modules M1 to M4, wherein the sensor DUT in the module M4 is arranged in the receptacle AUF, with a door DO provided in the module M4 to arrange the sensor DUT. Modules M1 to M4 extend the length L of the chamber K. It can be extended even further in its direction L by additional modules.

The wall insert WE is located in the wall W of the chamber K, with the antennas A1 and A2 that are connected to the respective transmitting/receiving transducers RX1, RX2, TX1 and TX2 via waveguides WL. The distance between the antennas A1 and A2 can therefore be changed until the sensor DUT is no longer able to detect the two antennas A1 and A2 as separate objects. The receiving and transmitting transducers RX1, RX2, TX1 and TX2 are connected to the computer RE, which controls the transmission/receiving devices SE1 and SE2 and evaluates the received signals and sends corresponding transmit signals. This is an exemplary illustration. In practice, it is quite possible and also common to provide one computing unit per transmission/receiving device, i.e., one computing unit per pair of transmitting and receiving transducers TX1/RX1, TX2/RX2.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A test arrangement for a sensor which is designed to perform object detection by sending first electromagnetic signals and by receiving second electromagnetic signals, the test arrangement comprising:
a chamber that has a receptacle for the sensor; and
at least two transmission/receiving devices that are set up to receive first signals sent from the sensor to the chamber and to transmit second signals for the sensor to receive,
wherein the at least two transmission/receiving devices each have one emitting element for emitting the second signals, and
wherein a spacer is provided with which a distance of the at least two emitting elements to one another can be changed in exactly one spatial direction.

2. The test arrangement according to claim 1, wherein the spacer has at least one rail via which the distance of the at least two emitting elements from one another is adapted to be changed in exactly one spatial direction.

3. The test arrangement according to claim 1, wherein the distance of the at least two transmission/receiving devices to one another is adapted to be changed in exactly one spatial direction via the spacer, and wherein the spacer has at least one rail via which the distance of the at least two transmission/receiving devices to one another is adapted to be changed in exactly one spatial direction.

4. The test arrangement according to claim 1, wherein the spacer has a first actuator for manually changing the distance and/or a second actuator for automatically changing the distance.

5. The test arrangement according to claim 1, wherein the chamber comprises several modules, wherein the modules extend the chamber in at least one direction, and wherein the direction extends from the sensor to the at least two emitting elements of the test arrangement.

6. The test arrangement according to claim 1, wherein the receptacle changes a position and/or an orientation of the sensor.

7. The test arrangement according to claim 1, wherein the chamber is substantially lined in its interior with a material absorbing the electromagnetic signals.

8. The test arrangement according to claim 1, wherein the at least two transmission/receiving devices each have a receiving element for receiving the first signals, wherein the emitting element and the receiving element of a respective transmission/receiving device are arranged in the interior of the chamber in a region of the wall of the chamber and the spacer is located outside the chamber.

9. The test arrangement according to claim 8, wherein the at least two transmission/receiving devices each comprise one transmitting transducer and one receiving transducer, wherein the transmitting transducer and the receiving transducer of a respective transmission/receiving device are located outside the chamber.

10. The test arrangement according to claim 9, wherein the area has a slot through which the respective emitting elements are connected via waveguides to the respective transmitting transducers and the respective receiving elements are connected via waveguides to the respective receiving transducers.

11. The test arrangement according to claim 10, wherein the slot on the inside of the chamber is substantially covered with the absorbent material.

12. The test arrangement according to claim 8, wherein the area is designed as a wall insert for an opening of the wall, and wherein the wall insert is used in at least two different orientations in the wall of the chamber.

13. The test arrangement according to claim 8, wherein the emitting element and the receiving element of a respective transmission/receiving device are formed as a combined emitting/receiving element.

14. The test arrangement according to claim 1, wherein the sensor is a radar sensor, wherein the emitting element a transmitting antenna, and wherein the receiving element is a receiving antenna.

15. The test arrangement according to claim 14, wherein the transmitting antenna and the receiving antenna of a respective transmission/receiving device are designed as one antenna, and wherein the antenna is a horn antenna or a curved antenna.

16. The test arrangement according to claim 15, wherein the area has a slot through which the respective antenna of a respective transmission/receiving device is connected to a transceiver via respective waveguides, and wherein the transceiver comprises the transmitting transducer and the receiving transducer of the respective transmission/receiving device.
